(19) United States
(12) Patent Application Publication
(10) Pub. No.: US 2025/0149479 A1
(43) Pub. Date: May 8, 2025

(54) SEMICONDUCTOR PACKAGE

(71) Applicant: SAMSUNG ELECTRONICS CO., LTD., Suwon-si (KR)

(72) Inventors: Haksun LEE, Suwon-si (KR); Dohyun Kim, Suwon-si (KR); Yeongseon Kim, Suwon-si (KR); Juhyeon Kim, Suwon-si (KR); Hyoeun Kim, Suwon-si (KR); Sunkyoung Seo, Suwon-si (KR); Chajea Jo, Suwon-si (KR)

(73) Assignee: SAMSUNG ELECTRONICS CO., LTD., Suwonl-si (KR)

(21) Appl. No.: 18/660,617

(22) Filed: May 10, 2024

(30) Foreign Application Priority Data
Nov. 6, 2023 (KR) 10-2023-0152083

(51) Int. Cl. H01L 23/00; H01L 23/48; H01L 25/10

(52) U.S. Cl. CPC H01L 24/06; H01L 23/481; H01L 24/05; H01L 24/08; H01L 24/80; H01L 25/105; H01L 2224/05624; H01L 2224/05639; H01L 2224/05644; H01L 2224/05647; H01L 2224/05655; H01L 2224/05666; H01L 2224/05681; H01L 2224/05686; H01L 2224/0603; H01L 2224/08145; H01L 2224/80379

(57) ABSTRACT

A semiconductor chip includes: a substrate; a plurality of upper pads on the substrate, the plurality of upper pads including a first group of the upper pads and a second group of the upper pads; a buffer layer covering a side surface of the first group of the upper pads; and an insulating layer surrounding a side surface of the second group of the upper pads and a side surface of the buffer layer on the substrate, wherein the buffer layer includes a first material having a first Young's modulus smaller than a second Young's modulus of a second material in the plurality of upper pads.

### CROSS-REFERENCE TO RELATED APPLICATION

This application is based on and claims priority under 35 U.S.C. § 119 to Korean Patent Application No. 10-2023-0152083, filed on Nov. 6, 2023, in the Korean Intellectual Property Office, the disclosure of which is incorporated by reference herein in its entirety.

### BACKGROUND

### 1. Field

The disclosure relates to a semiconductor package.

### 2. Description of Related Art

As demand for high capacity, reduced thickness, and miniaturization of electronic products has increased, various types of semiconductor packages have been developed. Recently, to integrate more components (e.g., semiconductor chips) into a package structure, a direct bonding technique of bonding semiconductor chips to each other without an adhesive film (e.g., non-conductive film (NCF)) or a connection bump (e.g., solder ball), has been developed.

### SUMMARY

Provided is a semiconductor package which may implement a stack of semiconductor chips having a bonding interfacial surface with improved quality and may have improved reliability.

According to an aspect of the disclosure, a semiconductor package includes: a first semiconductor chip including: a first substrate, a plurality of first upper pads on the first substrate, wherein the plurality of first upper pads includes a first group of the first upper pads and a second group of the first upper pads, a first buffer layer surrounding a side surface of the first group of the first upper pads, a first insulating layer surrounding a side surface of the second group of the first upper pads and a side surface of the first buffer layer, and a plurality of through-electrodes penetrating the first substrate, the plurality of through-electrodes being respectively connected to the plurality of the first upper pads; and a second semiconductor chip on the first semiconductor chip, including: a second substrate, a plurality of second lower pads below the second substrate, wherein the plurality of second lower pads includes a first group of the second lower pads and a second group of the second lower pads, a second buffer layer surrounding a side surface of the first group of the second lower pads, and a second insulating layer surrounding a side surface of the second group of the second lower pads and a side surface of the second buffer layer, wherein the first group of the first upper pads is respectively in contact with the first group of the second lower pads, and wherein the second group of the first upper pads is respectively in contact with the second group the second lower pads.

According to an aspect of the disclosure, a semiconductor package includes: a first semiconductor chip and a second semiconductor chip stacked in a vertical direction, wherein the first semiconductor chip includes: a plurality of first upper pads including: a first upper conductive layer, and a first upper seed layer surrounding a side surface of the first upper conductive layer and a lower surface of the first upper conductive layer; a first buffer layer extending along at least one perimeter of a first upper pad in a first set of the plurality of first upper pads; and a first insulating layer surrounding the first upper pad and the first buffer layer of a second set of the plurality of first upper pads, wherein the second semiconductor chip includes: a plurality of second lower pads including: a second lower conductive layer, and a second lower seed layer surrounding a side surface of the second lower conductive layer and an upper surface of the second lower conductive layer, the of the second lower conductive layer being electrically connected to the plurality of first upper pads; a second buffer layer extending along at least one perimeter of a second lower pad in a first set of the plurality of second lower pads; and a second insulating layer surrounding the second lower pad and the second buffer layer in a second set of the plurality of second lower pads, wherein the first buffer layer and the second buffer layer comprise a polymer or a porous metal.

According to an aspect of the disclosure, a semiconductor package includes: a first semiconductor chip including a plurality of upper pads; and a second semiconductor chip including: a plurality of lower pads including a first group of lower pads and a second group of the lower pads in contact with an upper surface of the plurality of upper pads, a connection conductor in contact with an upper surface of the first group of the lower pads, an internal insulating layer surrounding a side surface of the connection conductor, a buffer insulating layer in contact with a side surface of the first group of the lower pads and an upper surface of the second group of the lower pads, and an external insulating layer surrounding a side surface of the first group of the lower pads and a side surface of the second group of the lower pads below the buffer insulating layer, wherein the first group of the lower pads includes: a layer portion surrounded by the external insulating layer, and an extension portion extending from an upper surface of the layer portion, penetrating the buffer insulating layer, and being in contact with a lower surface of the connection conductor.

According to an aspect of the disclosure, a semiconductor chip includes: a substrate; a plurality of upper pads on the substrate, the plurality of upper pads including a first group of the upper pads and a second group of the upper pads; a buffer layer covering a side surface of the first group of the upper pads; and an insulating layer surrounding a side surface of the second group of the upper pads and a side surface of the buffer layer on the substrate, wherein the buffer layer includes a first material having a first Young's modulus smaller than a second Young's modulus of a second material in the plurality of upper pads.

### BRIEF DESCRIPTION OF DRAWINGS

The above and other aspects, features, and advantages in the example embodiment will be more clearly understood from the following detailed description, taken in combination with the accompanying drawings, in which:

FIG. 1 is a cross-sectional diagram illustrating a semiconductor package according to an example embodiment of the present disclosure;

FIG. 2A is an enlarged diagram illustrating a region “A” in FIG. 1;

FIG. 2B is a plan diagram illustrating a cross-sectional surface taken along line I-I′ in FIG. 2A;

FIGS. 3 to 15 are plan diagrams illustrating modified examples in relation to the region “A” in FIG. 2A;

FIGS. 16A to 16C are perspective diagrams illustrating a modified example in FIGS. 14 and 15 and graphs indicating experimental data;

FIGS. 17 and 18 are plan diagrams illustrating examples in relation to the region “A” in FIG. 2A;

FIG. 19 is a cross-sectional diagram illustrating a semiconductor package according to an example embodiment of the present disclosure;

FIG. 20A is a plan diagram illustrating a semiconductor package according to an example embodiment of the present disclosure;

FIG. 20B is a cross-sectional diagram illustrating a cross-sectional surface taken along line II-II′ in FIG. 20A;

FIGS. 21A to 21E are cross-sectional diagrams illustrating a process of manufacturing a semiconductor package in FIG. 2A;

FIGS. 22A to 22C are cross-sectional diagrams illustrating a process of manufacturing a semiconductor package in FIG. 4; and

FIGS. 23A to 23C are cross-sectional diagrams illustrating a process of manufacturing a semiconductor package in FIG. 14.

### DETAILED DESCRIPTION

Hereinafter, embodiments in the example embodiment will be described as follows with reference to the accompanying drawings.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

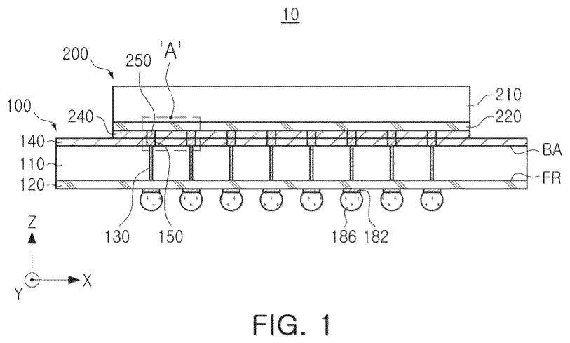

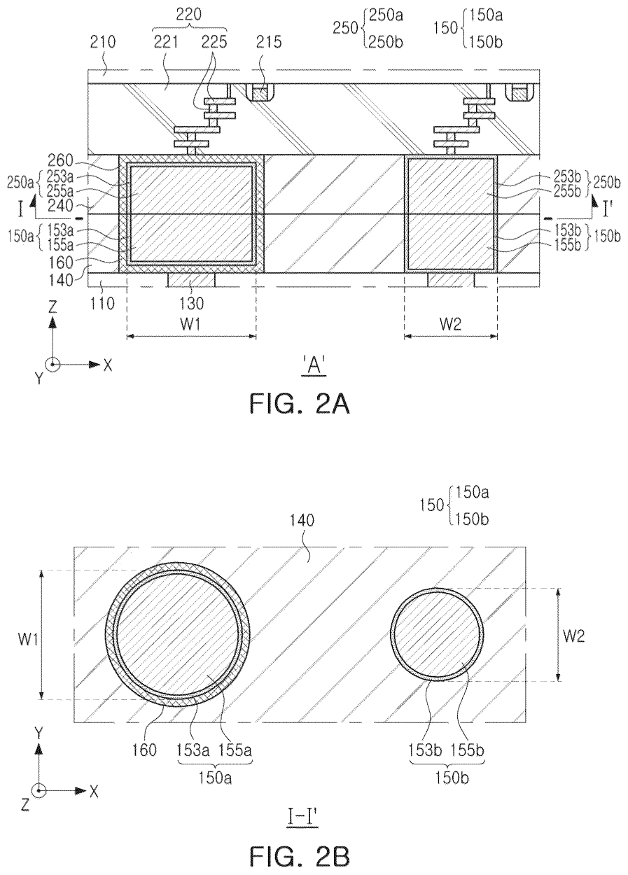

FIG. 1 is a cross-sectional diagram illustrating a semiconductor package 10 according to an example embodiment. FIG. 2A is an enlarged diagram illustrating a region “A” in FIG. 1. FIG. 2B is a plan diagram illustrating a cross-sectional surface taken along line I-I′ in FIG. 2A.

Referring to FIG. 1, the semiconductor package 10 in an example embodiment may include a plurality of semiconductor chips stacked in a vertical direction (e.g., Z-axis direction). For example, the plurality of semiconductor chips include a first semiconductor chip 100 and a second semiconductor chip 200.

In the first semiconductor chip 100 and the second semiconductor chip 200, an upper surface of the first semiconductor chip 100 and a lower surface of the second semiconductor chip 200 may be directly bonded and coupled to each other (for example, referred to as ‘hybrid bonding’ or ‘direct bonding’) without a connection member such as a metal bump. The first insulating layer 140 and the plurality of first upper pads 150 (, which provide an upper surface of the first semiconductor chip 100,) may be bonded and coupled to the second insulating layer 240 and a plurality of second lower pads 250, respectively, which provide a lower surface of the second semiconductor chip 200. The first semiconductor chip 100 and the second semiconductor chip 200 may be electrically connected to the plurality of first upper pads 150 and the plurality of second lower pads 250 directly bonded to each other.

Hereinafter, with reference to FIGS. 2A and 2B, components of the first semiconductor chip 100 and the second semiconductor chip 200 will be described in greater detail.

Hereinafter, a “first insulating layer 140” may be referred to as “first upper insulating layer” or “first back-surface insulating layer,” respectively, to distinguish positions of components in the first semiconductor chip 100. A “second insulating layer 240” may be referred to as a “second lower insulating layer” or a “second front-surface insulating layer” to distinguish positions of components in the second semiconductor chip 200. Also, a “first upper pad 150” may be referred to as a first pad” or a “first back-surface pad,” and a “second lower pad 250” may be referred to as a “second pad” or a “second front-surface pad.”

The first semiconductor chip 100 may include a first substrate 110, a first circuit layer 120, a plurality of first through-electrodes 130, a first insulating layer 140, a plurality of first upper pads 150, and a first buffer layer 160. The plurality of first upper pads 150 may include a first group of the first upper pads 150a and a second group of the first upper pads 150b.

The first substrate 110 may be a semiconductor wafer substrate having a front surface FR and a back surface BA that face each other. For example, the first substrate 110 may be a semiconductor wafer including a semiconductor element such as silicon and germanium, or a compound such as SiC (silicon carbide), GaAs (gallium arsenide), InAs (indium arsenide), and InP (indium phosphide). The front surface FR may be an active surface having an active region doped with impurities. The back surface BA may be an inactive surface disposed opposite to the front surface FR, with respect to the first substrate 110.

The first circuit layer 120 may be disposed on the front surface FR of the first substrate 110 and may include a first wiring structure connected to the active region and a first interlayer insulating layer surrounding the first wiring structure. The first wiring structure may form an integrated circuit with individual devices formed on the active surface of the first substrate 110. A first lower pad 182 electrically connected to the wiring structure may be disposed below the first circuit layer 120. The first lower pad 182 may be a pad structure electrically connected to the wiring structure. A connection bump 186 may be disposed below the first lower pad 182. The connection bump 186 may be, for example, a conductive bump structure including solder balls or copper (Cu) posts. The first circuit layer 120 may have a structure the same as or similar to that of the second circuit layer 220 illustrated in FIG. 2A. Accordingly, the above-described first wiring structure, the first interlayer insulating layer, and the individual devices may have properties similar to the second wiring structure 225, the second interlayer insulating layer 221, and the individual devices 215 of the second circuit layer 220 to be described later.

The plurality of through-electrodes 130 (or “a plurality of first through-electrodes”) may penetrate through the first substrate 110 and may electrically connect each of the first upper pad 150 to the first lower pad 182. The plurality of through-electrode 130 may include, for example, tungsten (W), titanium (Ti), aluminum (Al), copper (Cu), titanium (Ti), titanium nitride (TiN), tantalum (Ta), or tantalum nitride (TaN), and may be formed by a plating process, a physical vapor deposition (PVD) process, or a chemical vapor deposition (CVD) process. A side-surface insulating film, which includes an insulating material such as silicon oxide, silicon nitride, or silicon oxynitride (e.g., high aspect ratio process (HARP) oxide), may be formed between one through-electrode (of the plurality of through-electrodes 130) and the first substrate 110.

The first insulating layer 140 (or “a first upper insulating layer”) may be disposed on the back surface BA of the first substrate 110. The first insulating layer 140 may include an insulating material bonded and coupled to the second insulating layer 240 (or “a second lower insulating layer”) below the second semiconductor chip 200. For example, the first insulating layer 140 may include at least one of silicon oxide (SiO), silicon nitride (SiN), silicon oxynitride (SiON) and silicon carbonitride (SiCN). That is, at least a portion of the first insulating layer 140 may be bonded to the second insulating layer 240, and may form a ‘bonding interfacial surface’ that bonds and couples the first semiconductor chip 100 to the second semiconductor chip 200. Also, the first insulating layer 140 may be formed to surround the plurality of first upper pads 150 arranged on an upper surface of first insulating layer 140. The upper surfaces of the first insulating layer 140 may be substantially similar to upper surfaces of the plurality of first upper pads 150.

The plurality of first upper pads 150 may be disposed on the back surface BA of the first substrate 110, may be bonded to the second lower pads 250 of the second semiconductor chip 200, and may physically and electrically couple the first semiconductor chip 100 to the second semiconductor chip 200. The plurality of first upper pads 150 may include a first group of the first upper pads 150a and a second group of the first upper pads 150b. In an embodiment, as shown in FIG. 2A, the first width W1 of the first group of the first upper pads 150a may be greater than the second width W2 of the second group of the first upper pads 150b in a direction parallel to the upper surface of the first substrate 110 (e.g., X-direction or Y-direction). A side surface and a lower surface of the first group of the first upper pads 150a may be covered by the first buffer layer 160, and a side surface of the second group of the first upper pads 150b may be in direct contact with the first insulating layer 140. As illustrated in FIG. 2B, the plurality of first upper pads 150 may have a circular shape on the plane (X-Y plane), and a first buffer layer 160 may have a shape surrounding the first group of the first upper pads 150a of the first group. Embodiments of the disclosure are not limited to the above embodiments.

Each first upper pad 150 may include first upper conductive layers 155a and 155b and first seed layers 153a and 153b. The first seed layers 153a and 153b may cover side surfaces and lower surfaces of the first upper conductive layers 155a and 155b. The first upper conductive layers 155a and 155b may include at least one of copper (Cu), nickel (Ni), gold (Au), and silver (Ag). The first seed layers 153a and 153b may include at least one of titanium (Ti), titanium nitride (TiN), tantalum (Ta), and tantalum nitride (TaN).

The first buffer layer 160 may cover a side surface and a lower surface of the first group of the first upper pads 150a among the plurality of first upper pad 150. The first buffer layer 160 may alleviate expansion of the first group of the first upper pads 150a during a thermo-compression process for bonding and coupling of the first semiconductor chip 100 and the second semiconductor chip 200.

When the first width W1 of the first group of the first upper pads 150a is greater than the second width W2 of the second group of the second upper pads 150b, expansion properties of the first group of the first upper pads 150a during the thermo-compression process may be greater than expansibility (expansion properties) of the second group of the first upper pads 150b. When there is a difference in expansion properties of the plurality of first upper pads 150 during a bonding process, reliability of direct bonding may be reduced. The first buffer layer 160 may improve reliability of direct bonding by alleviating expansion properties of the first group of the first upper pads 150a, which may have greater expansion properties.

The first buffer layer 160 may include a material having a Young's modulus lower than that of a material in the plurality of first upper pads 150. Young's modulus is a coefficient indicating how a relative length of an elastic object changes in response to stress, and also referred to as an elastic modulus. Or, the Young's modulus of the first buffer layer 160 may be lower than a Young's modulus of each of the plurality of first upper pads 150.

For example, the first buffer layer 160 may include porous metal. Porosity may refer to a state of having several small voids (holes) in or on a surface of a solid object. A porous metal may have voids, such that a Young's modulus of the porous metal may be lower than that of a metal having no voids. For example, when the first upper pad 150 includes copper (Cu) and the first buffer layer 160 is formed of porous copper (Cu), even when the first upper pad 150 and the first buffer layer 160 include the same material, copper (Cu), the Young's modulus of the first buffer layer 160 may be lower than the Young's modulus of the first upper pad 150. For ease of description in the disclosure, a material described as “porous metal” may have a Young's modulus lower than that of a general “metal” material. For example, porous copper (Cu) may have a Young's modulus lower than that of copper (Cu). In an example embodiment, the first buffer layer 160 may include porous copper (Cu) or porous silver (Ag). As the first buffer layer 160 includes a conductive material such as a porous metal, the first group of the first upper pads 150a may be electrically connected to the at least one of the plurality of through-electrodes 130 through the first buffer layer 160.

The second semiconductor chip 200 may be disposed on the first semiconductor chip 100 and may include a second substrate 210, a second circuit layer 220, a second insulating layer 240, and a plurality of second lower pads 150. The second semiconductor chip 200 may have a flat lower surface corresponding to a lower surface of the second insulating layer 240 and the plurality of second lower pads 250. For example, a lower surface of the second insulating layer 240 and the lower surface of the second lower pads 250 exposed from the second insulating layer 240 may be substantially coplanar with each other. Since the first semiconductor chip 100 and the second semiconductor chip 200 may have substantially the same or similar structures, the same or similar components may be indicated by the same or similar reference numerals, and repeated descriptions of the same components may be omitted below. For example, the second substrate 210 may have substantially the same properties as that of the first substrate 110, as described above.

The second circuit layer 220 may be disposed on a front surface or an active surface of the second substrate 210, and may include a second wiring structure 225 connected to the active region and a second interlayer insulating layer 221 surrounding the second wiring structure 225.

The second interlayer insulating layer 221 may include flowable oxide (FOX), tonen SilaZen (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or combinations thereof. At least a portion of region of the second interlayer insulating layer 221 surrounding the second wiring structure 225 may be formed as a low-K layer. The second interlayer insulating layer 221 may be formed using CVD, a flowable-CVD process, or a spin coating process.

The second wiring structure 225 may be formed as a multilayer structure including, for example, a wiring pattern including aluminum (Al), gold (Au), cobalt (Co), copper (Cu), nickel (Ni), lead (Pb), tantalum (Ta), tellurium (Te), titanium (Ti), tungsten (W) or combinations thereof and a via. A barrier film including titanium (Ti), titanium nitride (TiN), tantalum (Ta), or tantalum nitride (TaN) may be disposed between the wiring pattern and/or via and the second interlayer insulating layer 221. Individual devices 215 in an integrated circuit may be disposed on a front surface of the second substrate 210. In this case, the second wiring structure 225 may be electrically connected to the individual devices 215 by an interconnection portion (e.g., a contact plug). The individual devices 215 may include a field-effect transistor (FET) such as planar FET and FinFET, a memory device such as flash memory, dynamic random access memory (DRAM), static random access memory (SRAM), electrically erasable programmable read-only memory (EEPROM), phase change random access memory (PRAM), magnetoresistive random access memory (MRAM), ferroelectric random access memory (FeRAM), and resistive random access memory (RRAM), a logic device such as AND, OR, NOT, and various active and/or passive devices such as system large-scale integration (LSI), complementary metal-oxide-semiconductor (CMOS) image sensor (CIS), micro-electro mechanical systems (MEMS).

The second insulating layer 240 (or a “second lower insulating layer”) may be disposed below the second substrate 210 or the second circuit layer 220 and may be formed to surround the plurality of second lower pads 250. The second insulating layer 240 may include an insulating material bonded and coupled to the first insulating layer 140 of the first semiconductor chip 100. For example, the second insulating layer 240 may include at least one of silicon oxide (SiO), silicon nitride (SiN), silicon oxynitride (SiON), and silicon carbonitride (SiCN). That is, at least a portion of the second insulating layer 240 may be bonded to the first insulating layer 140, and may form a ‘bonding interfacial surface’ that bonds and couples the first semiconductor chip 100 to the second semiconductor chip 200. Lower surfaces of the second insulating layer 240 may be substantially coplanar with lower surfaces of the plurality of second lower pads 250. The second insulating layer 240 may have properties similar to those of the first insulating layer 140.

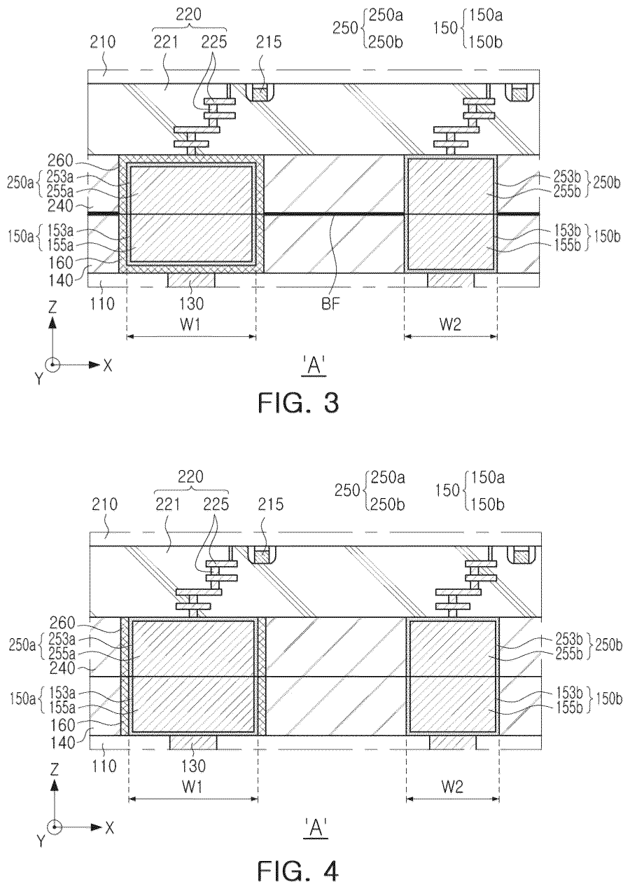

The plurality of second lower pads 250 may be bonded to the first upper pads 150 of the first semiconductor chip 100, thereby physically and electrically coupling the first semiconductor chip 100 to the second semiconductor chip 200. The plurality of second lower pads 250 may include a first group of the second lower pad 250a and a second group of the second lower pad 250b. For example, as shown in FIG. 3, the first group of the second lower pads 250a may have a width substantially equal to the first width W1 of the first group of the first upper pads 150a in a direction (e.g., X-direction or Y-direction) parallel to an upper surface of the second substrate 210. The second group of the second lower pads 250b may have substantially the same width as that of the second group of the first upper pads 150b. For example, as shown in FIG. 3, the first width W1 of the first group of the second lower pads 250a may be greater than the second width W2 of the second group of the second lower pads 250b. A side surface and an upper surface of the first group of the second lower pads 250a may be covered by the second buffer layer 260. A side surface of the second group of the second lower pads 250b may be in direct contact with the second insulating layer 240. Each second lower pad 250 may include second seed layers 253a and 253b (covering side surfaces and upper surfaces of the second lower conductive layers 253a and 253b) and the second lower conductive layers 255a and 255b. The second lower conductive layers 255a and 255b may include at least one of copper (Cu), nickel (Ni), gold (Au), and silver (Ag). The second seed layers 253a and 253b may include at least one of titanium (Ti), titanium nitride (TIN), tantalum (Ta), and tantalum nitride (TaN). The plurality of second lower pads 250 may have properties similar to that of the plurality of first upper pads 150.

The second buffer layer 260 may cover a side surface and an upper surface of the first group of the second lower pads 250a among the plurality of second lower pad 250. The second buffer layer 260 may alleviate expansion of the first group of the second lower pads 250a during a thermo-compression process for bonding and coupling the first semiconductor chip 100 to the second semiconductor chip 200. The second buffer layer 260 may improve reliability of direct bonding by alleviating expansion properties of the first group of the second lower pads 250a. The second buffer layer 260 may have properties that are same as or similar to properties of the first buffer layer 160, which is described above. The first group of the second lower pads 250a may be electrically connected to the second wiring structure 225 through the second buffer layer 260.

Bonding and coupling of the first semiconductor chip 100 to the second semiconductor chip 200 may be performed by operations described as below.

First, a planar surface may be formed by applying a polishing process to an upper surface of the first insulating layer 140 and a lower surface of the second insulating layer 240. The polishing process may include a chemical mechanical polishing (CMP) process.

Thereafter, the upper surface of the first insulating layer 140 and the lower surface of the second insulating layer 240 may be disposed to oppose each other, and pressure may be applied to form coupling by force, for example, van der Waals force.

Thereafter, through a low-temperature annealing process, the upper surface of the first insulating layer 140 and the lower surface of the second insulating layer 240 may be shared-coupled to each other, and the coupling may be strengthened. The low-temperature annealing process may be performed, for example, at about 100° C. to 200° C. Embodiments of the disclosure are not limited to the above embodiments.

After the upper surface of the first insulating layer 140 and the lower surface of the second insulating layer 240 are coupled to each other, the upper surface of the plurality of first upper pads 150 and the lower surface of the plurality of second lower pads 250 may be coupled to each other by mutual diffusion through a high-temperature annealing process that may be performed at approximately 200° C. to 400° C. Embodiments of the disclosure are not limited to the above embodiments.

Since widths of the first group of the first upper pad 150a and the first group of the second lower pads 250a are greater than those of the second group of the first upper pad 150b and the second group of the second lower pads 250b, the first group of the pads may have greater expansion properties during heat treatment than the second group of the pads, which may impede stability of the coupling. In an example embodiment, by including the first buffer layer 160 and the second buffer layer 260 surrounding the first group of the pads, expansion properties of the first group of the pads may be alleviated and bonding having improved reliability may be obtained.

In FIG. 2A, both the first buffer layer 160 and the second buffer layer 260 may be present, but in example embodiments, only the first buffer layer 160 or only the second buffer layer 260 may be presented.

After bonding is performed, interfacial surfaces of the first insulating layer 140 and the second insulating layer 240 may not be clearly distinct. Interfacial surfaces of the plurality of first upper pads 150 and the plurality of second lower pads 250 may also not be clearly distinct. In example embodiments, ‘the first insulating layer 140 and the second insulating layer 240,’ ‘the plurality of first upper pads 150 and the plurality of second lower pads 150,’ ‘the first buffer layer 160 and the second buffer layer 260’ may each be described as an integrated component. For example, the first insulating layer 140 and the second insulating layer 240 may be referred to as integrated bonding insulating layers 140 and 240. The plurality of first upper pads 150 and the plurality of second lower pads 250 may be referred to as a plurality of bonding pads 150 and 250. The first buffer layer 160 and the second buffer layer 260 may be referred to as bonding buffer layers 160 and 260.

The above descriptions with reference to FIGS. 1 to 2B relate to an example embodiment of a semiconductor package. In some embodiments, in a portion in which the first semiconductor chip 100 and the second semiconductor chip 200 are bonded to each other, the number and the shape of plurality of first upper pads 150 and the plurality of second lower pads 250 and a spacing therebetween may be varied, and a portion of the pads may be a dummy pad not electrically connected to other components.

In the description below, descriptions overlapping those described with reference to FIGS. 1 to 2C will be omitted.

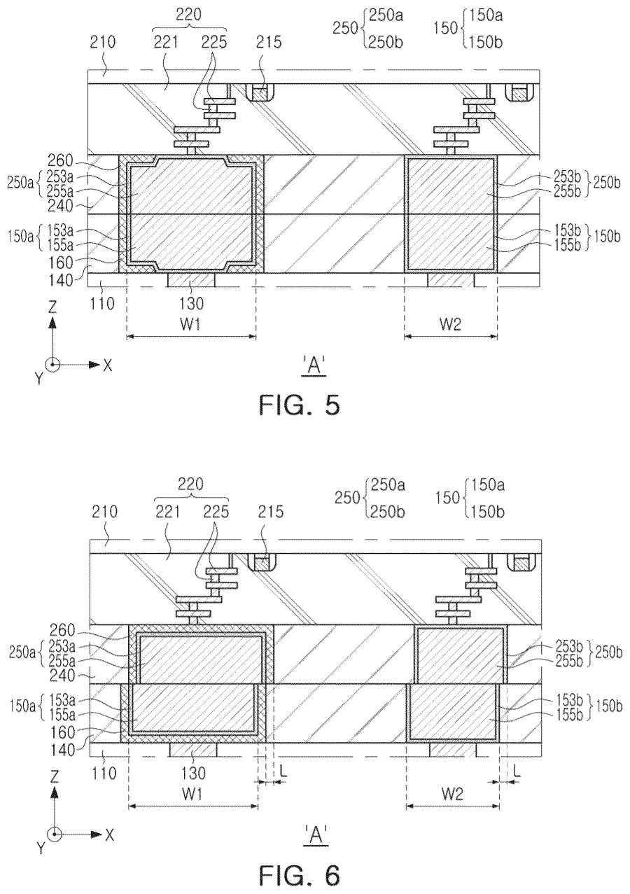

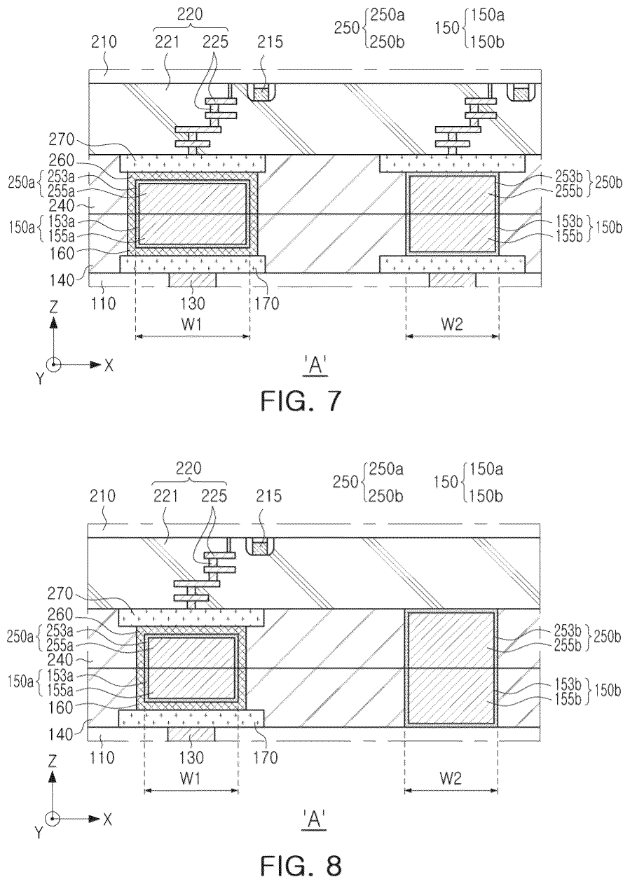

FIGS. 3 to 15 are plan diagrams illustrating modified examples in relation to the region “A” in FIG. 2A. The descriptions referring to FIGS. 3 to 15 relate to an example embodiment, and the bonding and coupling between the first semiconductor chip 100 and the second semiconductor chip 200 may be varied. The embodiments in which the modified examples of FIGS. 3 to 15 are applied to the first semiconductor chip 100 and the second semiconductor chip 200 may be varied. For example, the region “A” on the first semiconductor chip 100 may have the shape in FIG. 4, and the region “A” below the second semiconductor chip 200 may have the shape in FIG. 5. That is, in a compatible range, various modified examples may be mixed for the first semiconductor chip 100 and the second semiconductor chip 200.

Referring to FIG. 3, a bonding film BF may be present between the first insulating layer 140 and the second insulating layer 240. The bonding film BF may include a material facilitating bonding and coupling between the first semiconductor chip 100 and the second semiconductor chip 200. The bonding film BF may include a material that is the same as or different from that of the first insulating layer 140 and the second insulating layer 240. For example, the bonding film BF may include at least one of silicon oxide (SiO), silicon nitride (SiN), silicon oxynitride (SiON), or silicon carbonitride (SiCN).

Referring to FIG. 4, the first buffer layer 160 may surround a side surface of the first group of the first upper pads 150a. A lower surface of the first group of the first upper pads 150a may be in direct contact with the at least one of the plurality of through-electrodes 130. Similarly to the example described with reference to FIG. 2, the first buffer layer 160 may cover a side surface of the first group of the first upper pads 150a, thereby reducing expansion properties of the first group of the first upper pads 150a during a heat treatment. As in the example embodiment, when the first group of the first upper pads 150a is in direct contact with at least one of the plurality of through-electrodes 130, the first buffer layer 160 may use an insulating material (e.g., a polymer or a porous metal). The polymer included in the first buffer layer 160 may have a Young's modulus lower than that of a conductive material in the first upper pad 150a. Similarly, the second buffer layer 260 may surround a side surface of the first group of the second lower pads 250a. An upper surface of the first group of the second lower pads 250a may be in direct contact with the second circuit layer 220 and may be directly electrically connected to the second wiring structure 225.

Referring to FIG. 5, the first buffer layer 160 may cover a side surface and a lower surface of the first group of the first upper pads 150a. The first group of the first upper pads 150a may penetrate a lower surface of the first buffer layer 160 and may be in direct contact with and electrically connected to the at least one of the plurality of through-electrodes 130. The first buffer layer 160 may include a conductive material (such as a porous metal) and, also, an insulating material (such as a polymer). Similarly, the first group of the second lower pads 250a penetrates through an upper surface of the second buffer layer 260 and may be in direct contact with the second circuit layer 220 and may be electrically connected to the second wiring structure 225.

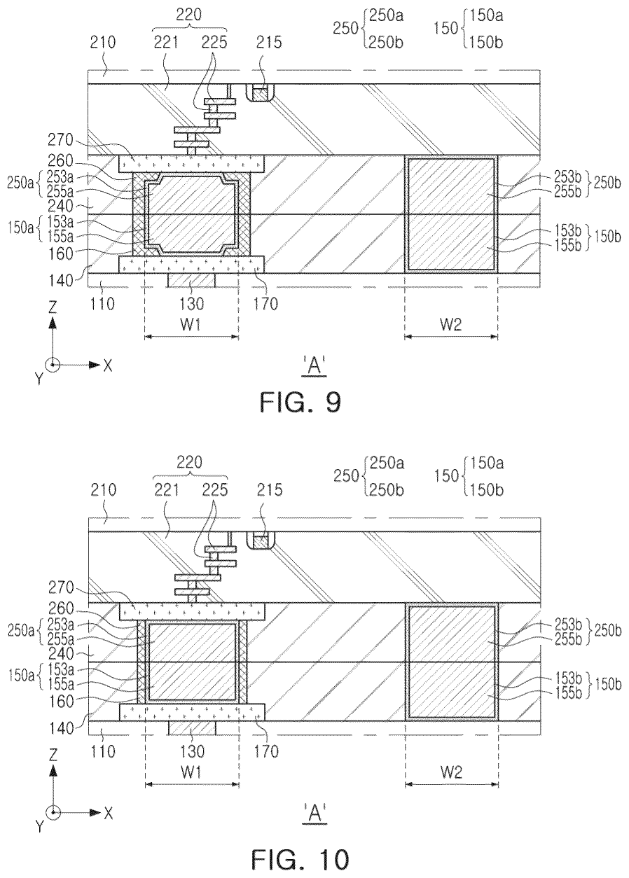

Referring to FIG. 6, the plurality of first upper pads 150 and the plurality of second lower pads 250 may be in contact with and shifted from each other. For example, the plurality of second lower pads 250 may be shifted from each other by a predetermined distance L in the horizontal direction (e.g., X-direction). At least a portion of an upper surface of the first upper pad 150 may be in contact with at least a portion of a lower surface of the second lower pad 250.

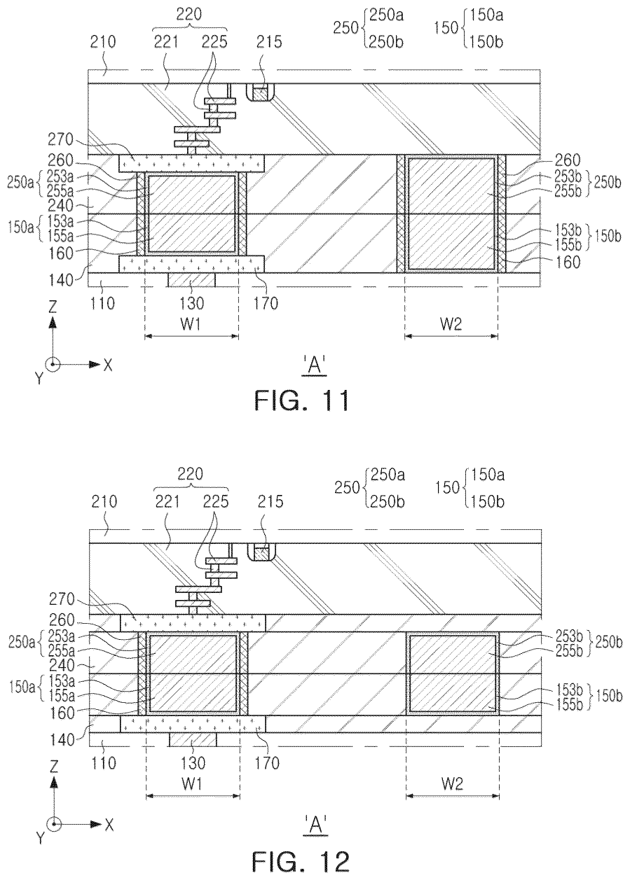

Referring to FIG. 7, the first semiconductor chip 100 may further include a first connection conductor 170. The first connection conductor 170 may be disposed between the plurality of first upper pads 150 and the first substrate 110 in the first insulating layer 140. The first connection conductor 170 may be in direct contact with an upper surface (or the back surface BA shown in FIG. 1) of the first substrate 110, and may electrically connect the at least one of the plurality of through-electrodes 130 to the first upper pad 150. Even in this case, the first buffer layer 160 may alleviate expansion properties of the first group of the first upper pads 150a during bonding. Thus, even when the first width W1 of the first group of the first upper pads 150a is greater than the second width 150b of the second group of the first upper pads 150b, reliability of the bonding may be improved. A width of the first connection conductor 170 in the horizontal direction (e.g., X-direction) may be greater than the first width W1 and the second width W2. The first connection conductor 170 may include at least one of aluminum (Al), copper (Cu), or an alloy of those components. Embodiments of the disclosure are not limited to the above embodiments.

The second semiconductor chip 200 may include a second connection conductor 270 in contact with an upper surface of the plurality of second lower pads 250 below the second substrate 210. In example embodiments, the second connection conductor 270 may present only on the first group of the second lower pads 250a, or may present only on the second group of the second lower pads 250b. The second connection conductor 270 may have properties that is the same as or similar to that of the first connection conductor 170 of the first semiconductor chip 100. The second connection conductor 270 may be disposed between the plurality of second lower pads 250 and the second circuit layer 220 in the second insulating layer 240. The second connection conductor 270 may be in direct contact with a lower surface of the second circuit layer 220, and may electrically connect the second wiring structure 225 to the second lower pad 250.

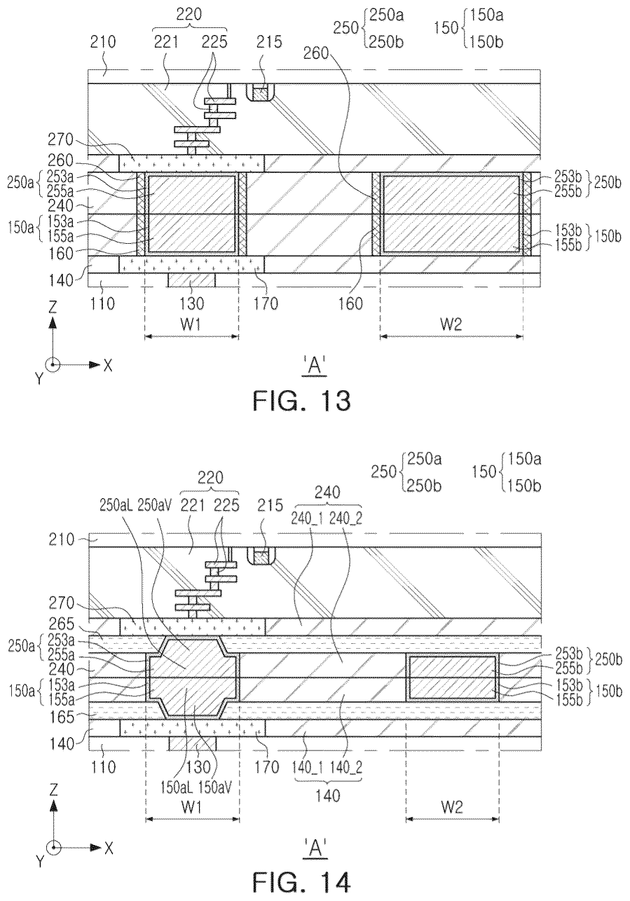

Referring to FIG. 8, the second group of the first upper pads 150b and the second group of the second lower pads 250b may be dummy pads not electrically connected to surrounding components. The first connection conductor 170 may be electrically connected to and in direct contact with at least one of the plurality of through-electrodes 130 below the first group of the first upper pads 150a. The second connection conductor 270 may be electrically connected in direct contact with the second wiring structure 225 on the first group of the second lower pads 250a. The first connection conductor 170 may increase expansion properties of the adjacent first group of the first upper pad 150a when bonding. Accordingly, even when the first width W1 of the first group of the first upper pads 150a is substantially the same as the second width W2 of the second group of the second upper pad 150b, expansion properties of the first group of the first upper pads 150a may be greater. The first buffer layer 160 covering a side surface and a lower surface of the first group of the first upper pads 150a alleviate expansion properties of the first group of the first upper pads 150a and may improve reliability of the bonding. Similarly, the second buffer layer 260 may alleviate expansion properties of the adjacent first group of the second lower pad 250a and may improve reliability of the bonding.

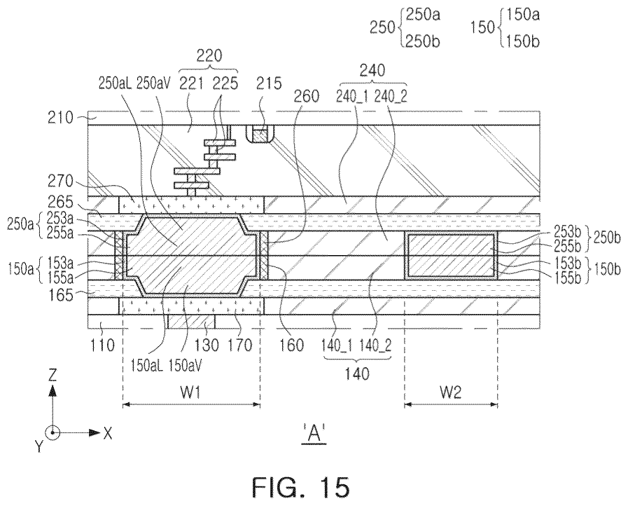

Referring to FIG. 9, the first group of the first upper pads 150a may penetrate the first buffer layer 160 and may be in direct contact with the first connection conductor 170. Accordingly, the first buffer layer 160 may include an insulating material and, also, a conductive material. The first group of the second lower pads 250a may penetrate the second buffer layer 260 and may be in direct contact with the second connection conductor 270, and the second buffer layer 260 may include an insulating material also a conductive material. Each component in FIG. 9 may have properties that are the same as or similar to each corresponding component described with reference to FIG. 8.

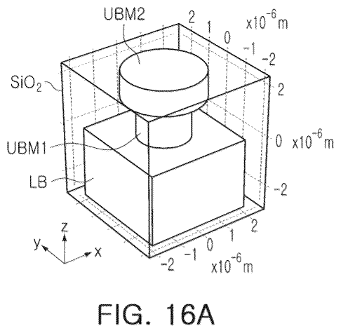

Referring to FIG. 10, differently from the example embodiment in FIGS. 8 and 9, the first buffer layer 160 may cover a side surface of the first group of the first upper pads 150a, and a lower surface of the first group of the first upper pads 150a may be in direct contact with the first connection conductor 170. Similarly, the second buffer layer 260 may cover a side surface of the first group of the second lower pads 250a, and an upper surface of the first group of the second lower pads 250a may be in direct contact with the lower surface of the second circuit layer 220 and may be electrically connected to the second wiring structure 225.

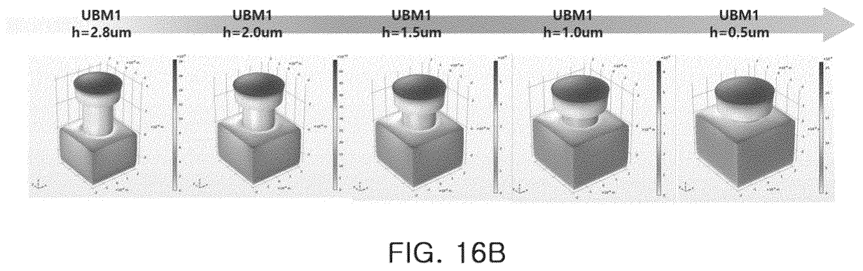

Referring to FIG. 11, the first buffer layer 160 may cover a side surface of the first group of the first upper pads 150a and also the second group of the first upper pads 150b. The first buffer layer 160 may alleviate expansion during bonding of adjacent plurality of first upper pads 150 and may improve reliability of bonding. The second buffer layer 260 may also cover a side surface of the first group of the second lower pads 250a and also the second group of the second lower pads 250b and may improve bonding reliability. The embodiment in which the first buffer layer 160 and the second buffer layer 260 cover the plurality of first upper pads 150 and the second lower pads 250 is not limited thereof, and may be varied as in the aforementioned example embodiment.

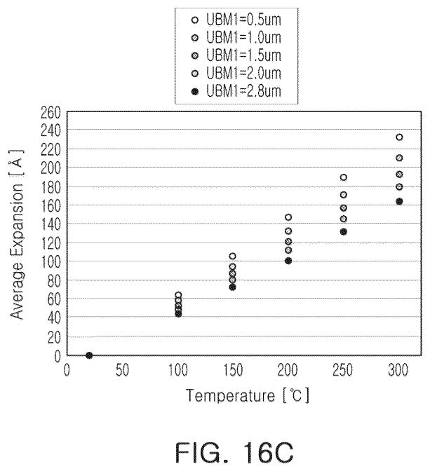

Referring to FIG. 12, the second group of the first upper pads 150b may have properties that are the same as similar to the example embodiment in FIG. 8 other than the configuration in which the second group of the first upper pads 150b may be spaced apart from an upper surface of the first substrate 110 by a thickness of the first connection conductor 170. The second group of the second lower pads 250b may be spaced apart from the second circuit layer 220 by a thickness of the second connection conductor 270.

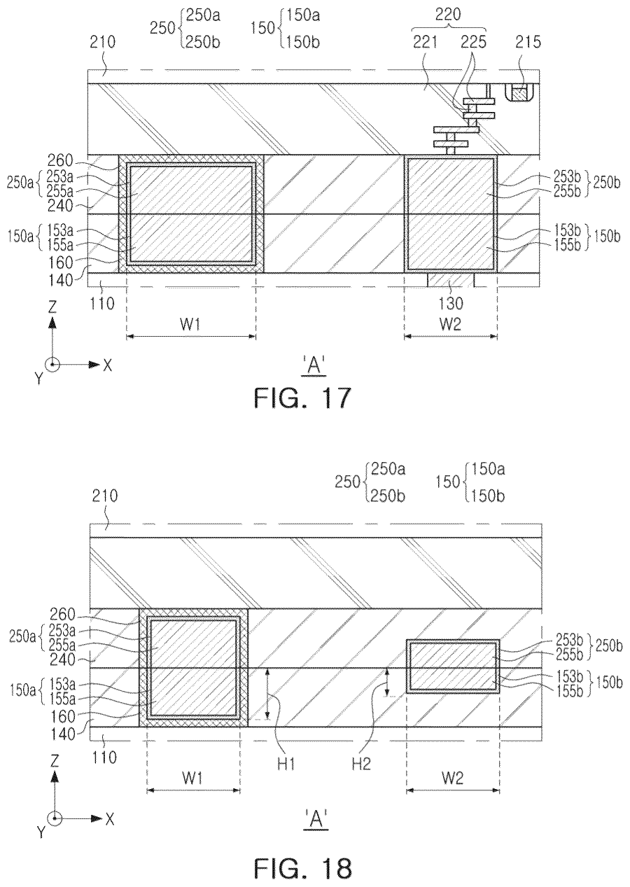

Referring to FIG. 13, the second width W2 of the second group of the first upper pads 150b may be greater than the first width W1 of the first group of the first upper pads 150a. The first buffer layer 160 may cover the second group of the first upper pads 150b and, also, a side surface of the first group of the first upper pads 150a. The first buffer layer 160 (, which is adjacent to the first group of the first upper pads 150a,) may alleviate expansion properties of the first group of the first upper pads 150a, which is increased by the first connection conductor 170. The first buffer layer 160 (adjacent to the second group of the first upper pads 150b) may alleviate the increased expansion of the second group of the first upper pads 150b with the second width W2. The width of the first buffer layer 160 (covering the first group of the first upper pads 150a) and the width of the first buffer layer 160 (covering the second group of the second upper pad 150b) may be the same or different in example embodiments.

For example, when it is necessary to further reduce expendability of the first group of the first upper pads 150a, the width of the first buffer layer 160 (in contact with the first group of the first upper pads 150a) may be greater than the width of the first buffer layer 160 in contact with the second group of the first upper pads 150b. The second buffer layer 260 of the second semiconductor chip 200 may have properties that are the same as or similar to that of the first buffer layer 160 of the first semiconductor chip 100.

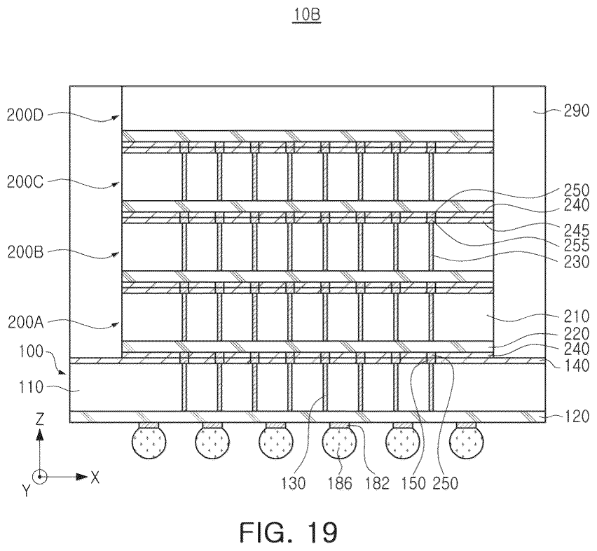

Referring to FIG. 14, the first semiconductor chip 100 may include a first buffer insulating layer 165 dividing the first insulating layer 140 into a first internal insulating layer 140_1 and a first external insulating layer 140_2. The first internal insulating layer 140_1 may surround a side surface of the first connection conductor 170 on the first substrate 110. The first buffer insulating layer 175 may be disposed on the first internal insulating layer 140_1 and the first connection conductor 170, and may be in contact with a side surface of the first group of the first upper pads 150a and a lower surface of the second group of the first upper pads 150b. The first group of the first upper pads 150a may include an extension portion 150aV extending from the first layer portion 150aL on the first buffer insulating layer 175 and a lower surface of the first layer portion 150aL, penetrating the first buffer insulating layer 175, and being in contact with the first connection conductor 170. The first external insulating layer 140_2 may surround the first layer portion 150aL on the first buffer insulating layer 175.

As the first layer portion 150aL is spaced apart from the first connection conductor 170, expendability of the first group of the first upper pads 150a (increased by the first connection conductor 170) may be alleviated, and thus, reliability of the bonding may be improved. The second semiconductor chip 200 may include a second connection conductor 270 (having properties similar to that of the first connection conductor 170) and a second buffer insulating layer 265 (having properties similar to that of the first buffer insulating layer 165). The second connection conductor 270 may be in contact with an upper surface of the first group of the second lower pads 250a below the second circuit layer 220. The second internal insulating layer 240_1 may surround a side surface of the second lower pad 250a. The second buffer insulating layer 265 may surround the first group of the second lower pads 250a below the second internal insulating layer 240_1 and may be in contact with an upper surface of the second group of the second lower pads 250b. The second external insulating layer 240_2 may surround the first group of the second lower pads 250a. The second group of the second lower pads 250b below the second buffer insulating layer 265.

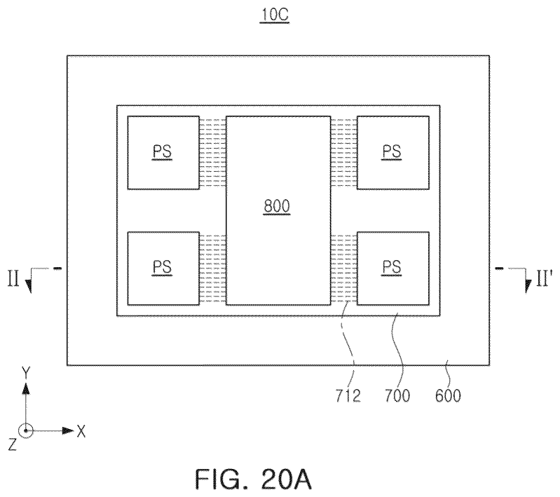

Referring to FIG. 15, the first semiconductor chip 100 may further include the first buffer layer 160 covering a side surface of the first group of the first upper pads 150a. Accordingly, even when the first width W1 of the first group of the first upper pads 150a in contact with the first connection conductor 170 is greater than the second width W2 of the second group of the second upper pad 150b, expansion properties of the first group of the first upper pads 150a may be alleviated and bonding reliability may be improved. The second semiconductor chip 200 may include the second buffer layer 260. Descriptions of the above mentioned elements will be omitted.

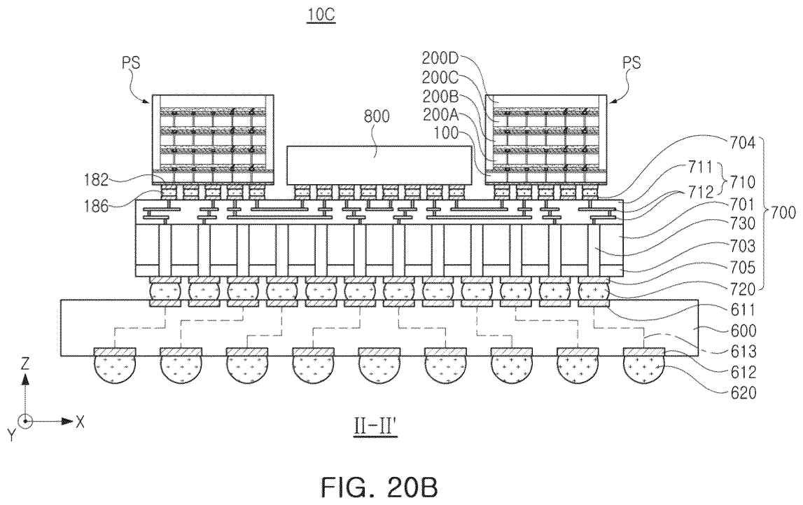

FIGS. 16A to 16C are perspective diagrams illustrating a modified example in FIGS. 14 and 15 and graphs indicating experimental data. The descriptions of FIGS. 16A to 16C will be provided in reference to FIGS. 14 to 15.

The image in FIG. 16A may represent a conductive structure including a layer portion and an extension portion, and UBM1, UBM2, and LB in the image in FIG. 16A may correspond to the components in FIGS. 14 to 15, respectively. UBM1 may correspond to the first extension portion 150aV or the second extension portion 250aV, UBM2 may correspond to the first layer portion 150aL or the second layer portion 250aL, and LB may correspond to the first connection conductor 170 or the second connection conductor 270. FIG. 16B indicate that as the thickness h of UBM1 decreases from 2.8 μm to 0.5 μm, UBM2 expands more significantly during heat treatment. The graph in FIG. 16C similarly indicate an average expansion value of UBM2 according to temperature increase when the thickness of UBM1 varies from 0.5 μm to 2.8 μm.

UBM2 electrically connected to LB may have greater expansion properties during the heat treatment process for bonding. Expansion properties may be alleviated as a thickness of UBM1 increases, that is, a distance at which UBM2 is spaced apart from LB increases. For example, when the thickness of UBM1 is 0.5 μm during heat treatment at 300° C., an average expansion value of UBM2 may be between 220 Angstroms (Å) and 240 Angstroms (Å), but when the thickness of UBM1 is 2.8 μm, the average expansion value of UBM2 may be between 160 Angstroms (Å) and 180 Angstroms (Å). As the first group of the first upper pads 150a is in contact with the first connection conductor 170, even though the upper pad 150a expands more significantly during heat treatment than the second group of the first upper pads 150b, by ensuring a sufficient thickness of the first extension portion 150aV, expansion of the first layer portion 150aL may be alleviated. Also, as illustrated in FIG. 15, by including the first buffer layer 160 in contact with the first layer portion 150aL, expansion properties of the first layer portion 150aL may be further alleviated and hybrid coupling by heat treatment may be performed stably. The descriptions of the first group of the second lower pad 250a, the second connection conductor 270, and the second buffer layer 260 overlapping the above descriptions will not be provided.

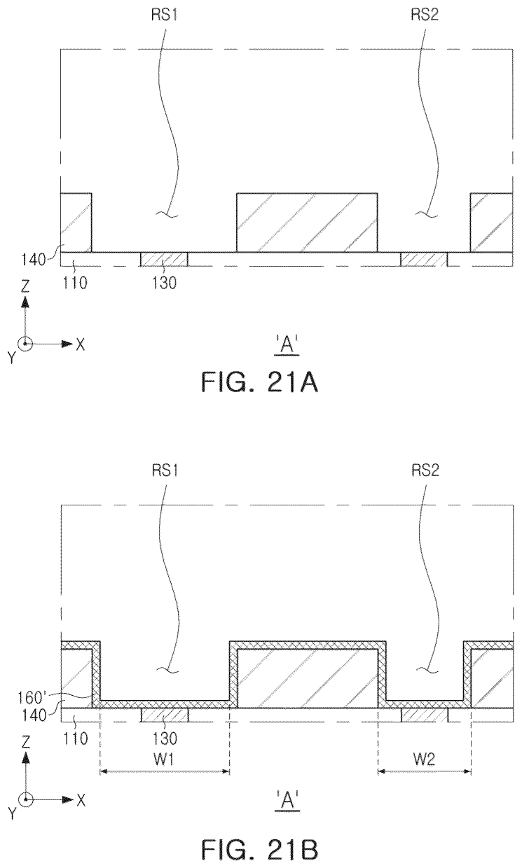

Referring to FIG. 17, the first group of the first upper pads 150a (surrounded by the first buffer layer 160) may be a dummy pad not electrically connected to other components. The first width W1 of the first group of the first upper pads 150a, which is a dummy pad, may be greater than the first width W2 of the second group of the second upper pad 150b, which is electrically connected to other components. The first buffer layer 160 may surround at least a portion of a side surface and a lower surface of the first group of the first upper pads 150a. The first buffer layer 160 may include an insulating material (such as a polymer) in addition to a conductive material (such as a porous metal). The first group of the second lower pads 250a surrounded by the second buffer layer 260 may have properties that are the same as or similar to the first group of the first upper pads 150a. The second buffer layer 260 may cover at least a portion of a side surface and an upper surface of the first group of the second lower pads 250a, and may have properties that are the same as or similar to the first buffer layer 160.

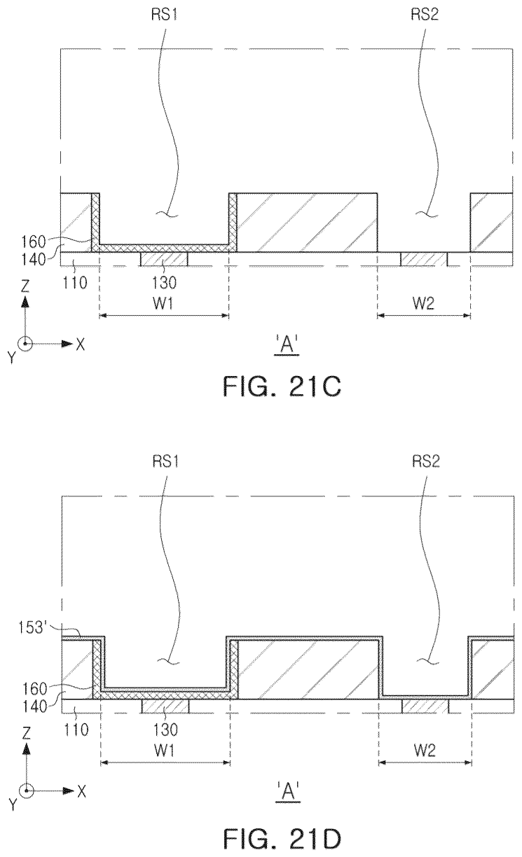

Referring to FIG. 18, the first group of the first upper pads 150a and the second group of the first upper pads 150b may be dummy pads that are not electrically connected to other components. In an embodiment, in a sub-region of the region “A” in FIG. 18, a third group of pads, which electrically connect the first semiconductor chip 100 to the second semiconductor chip 200, may be present. The first thickness H1 of the first group of the first upper pads 150a may be greater than the second thickness H2 of the second group of the second upper pad 150b in a direction perpendicular to an upper surface of the first substrate 110 (e.g., Z-direction). Even when the first width W1 of the first upper pad 150a is substantially the same as the second width W2 of the second group of the first upper pads 150b, expansion properties of the first group of the first upper pads 150a may be greater than those of the second group of the first upper pads 150b during the bonding. The first buffer layer 160 may surround at least a portion of a side surface and a lower surface of the first upper pad 150a of the first group and may alleviate expansion properties of the first group of the first upper pads 150a. The first group of the second lower pads 250a, the second group of the second lower pad 250b, and the second buffer layer 260 have properties that are the same as or similar to those of the first group of the first upper pads 150a, the second group of the first upper pads 150b, and the first buffer layer 160, respectively.

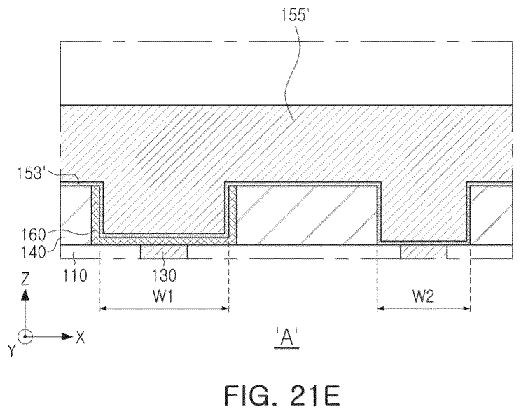

Referring to FIG. 19, the semiconductor package 10B in an example embodiment may have properties that are the same as or similar to the examples described with reference to FIGS. 1 to 18 other than the configuration in which a plurality of second semiconductor chips 200A, 200B, 200C, and 200D and a molding member 290 stacked in the vertical direction (Z-axis direction) are included in on the first semiconductor chip 100.

For example, the first semiconductor chip 100 may include a plurality of first upper pads 150. The plurality of first upper pads 150 may include the first group of the first upper pads 150a and the second group of the first upper pads 150b described with reference to FIGS. 2A to 18. Each of the plurality of second semiconductor chips 200A, 200B, 200C, and 200D may include the plurality of second lower pads 250. The plurality of second lower pads 250 may include the first group of the second lower pads 250a and the second group of the second lower pads 250b described with reference to FIGS. 2A to 18. The plurality of second semiconductor chips 200A, 200B, 200C, and 200D may include a plurality of second upper pads 255 and a second upper insulating layer 245, which have properties that are the same as or similar to the plurality of first upper pads 150 and the first insulating layer 140, respectively.

A bonding interfacial surface on which the second lower insulating layer 240 is bonded to the second upper insulating layer 245. The plurality of second lower pads 250 are bonded to the plurality of second upper pads 255 may be formed between the plurality of second semiconductor chips 200A, 200B, 200C, and 200D. The plurality of second semiconductor chips 200A, 200B, 200C, and 200D may be electrically connected to each other by the second lower pad 250 and the second upper pad 255 that are bonded to each other. Among the plurality of second semiconductor chips 200A, 200B, 200C, and 200D, the lowermost second semiconductor chip 200A may be electrically connected to the first semiconductor chip 100 by the plurality of second lower pads 250 and the plurality of first upper pads 150 of the first semiconductor chip 100.

The plurality of second semiconductor chips 200A, 200B, 200C, and 200D may have properties that are the same as or similar to the second semiconductor chip 200 described with reference to FIGS. 1 to 18 other than the configuration in which the second through-electrode 230 to form a mutual electrical connection path may be further included. However, the uppermost second semiconductor chip 200D may not have the second through-electrode 230. In example embodiments, the uppermost second semiconductor chip 200D may have a relatively greater thickness. Accordingly, in the example embodiment, more or fewer semiconductor chips than the examples illustrated in the drawing may be stacked on the first semiconductor chip 100. For example, less than three or more than five semiconductor chips may be stacked on the first semiconductor chip 100.

As an example, the first semiconductor chip 100 may be a buffer chip or a control chip including a plurality of logic devices or memory devices. The first semiconductor chip 100 may transmit signals from the plurality of second semiconductor chips 200A, 200B, 200C, and 200D stacked in an upper portion to an external entity, and may also transmit signals and power from an external entity to the plurality of second semiconductor chips 200A, 200B, 200C, and 200D. The plurality of second semiconductor chips 200A, 200B, 200C, and 200D may be memory chips including volatile memory devices such as DRAM and SRAM, or non-volatile memory devices such as PRAM, MRAM, FeRAM, or RRAM.

The molding member 290 may be disposed on the first semiconductor chip 100 and may encapsulate at least a portion of each of the plurality of second semiconductor chips 200A, 200B, 200C, and 200D. The molding member 290 may be formed to expose an upper surface of the uppermost second semiconductor chip 200D. However, in example embodiments, the molding member 290 may be formed to cover an upper surface of the uppermost second semiconductor chip 200D. The molding member 290 may include, for example, epoxy mold compound (EMC), but materials of the molding member 290 are not limited to any particular example.

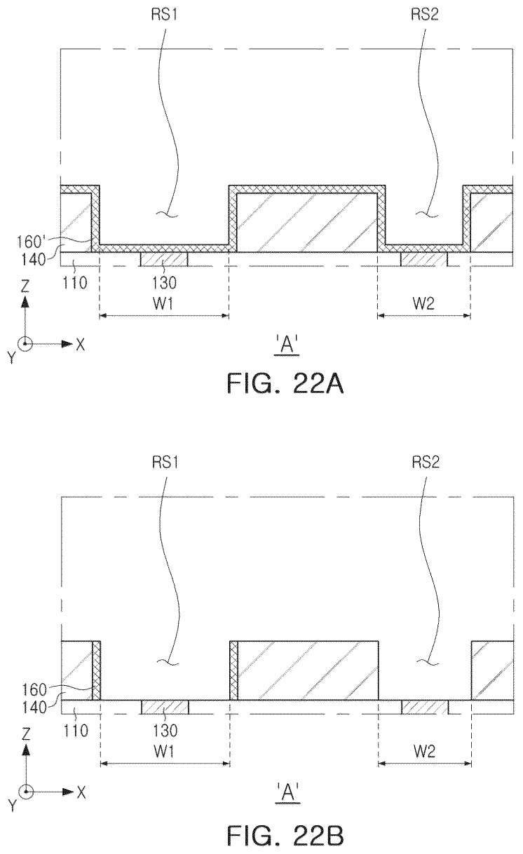

FIG. 20A is a plan diagram illustrating a semiconductor package according to an example embodiment. FIG. 20B is a cross-sectional diagram illustrating a cross-sectional surface taken along line II-II′ in FIG. 20A.

Referring to FIGS. 20A and 20B, a semiconductor package 10C in an example embodiment may include a package substrate 600, an interposer substrate 700, and at least one package structure PS. Also, the semiconductor package 10C may further include a logic chip (or a processor chip) 800 disposed adjacent to the package structure PS on the interposer substrate 700. The package structure PS may have properties that are the same as or similar to the semiconductor packages described with reference to FIGS. 1 to 18. The package structure PS may be implemented as the semiconductor package 10B illustrated in FIG. 19. Embodiments of the disclosure are not limited to the above embodiments.

Package substrate 600 may be a support substrate on which the interposer substrate 700, the logic chip 800, and the package structure PS are mounted, and may be a substrate for semiconductor package including a printed circuit board (PCB), ceramic substrate, glass substrate, tape wiring substrate, or the like. The package substrate 600 may include a lower pad 612, an upper pad 611, and a wiring circuit 613 electrically connecting the lower pad 612 to the upper pad 611. A body of the package substrate 600 may include different materials depending on the type of substrate. For example, when the package substrate 600 is a printed circuit board, the package substrate 600 may be a body copper-clad laminate or a wiring layer additionally stacked on one or both surfaces of the copper-clad laminate. The upper pad 611, the lower pads 612 and the wiring circuit 613 may form an electrical path connecting a lower surface and an upper surface of the package substrate 600 to each other. An external connection bump 620 connected to the lower pad 612 may be disposed on a lower surface of the package substrate 600. The external connection bump 620 may include, for example, a solder ball.

The interposer substrate 700 may include a substrate 701, a lower protective layer 703, a lower pad 705, an interconnection structure 710, a conductive bump 720, and a through-via 730. The package structure PS and the processor chip 800 may be stacked on the package substrate 600 using the interposer substrate 700. The interposer substrate 700 may electrically connect the package structure PS and the processor chip 800 to each other.

The substrate 701 may be formed of, for example, at least one of silicon, organic, plastic, and glass substrates. When the substrate 701 is a silicon substrate, the interposer substrate 700 may be referred to as a silicon interposer. In some embodiments, when the substrate 701 is an organic substrate, the interposer substrate 700 may be referred to as a panel interposer.

The lower protective layer 703 may be disposed on a lower surface of the substrate 701, and the lower pad 705 may be disposed on the lower protective layer 703. The lower pad 705 may be connected to the through-via 730. The package structure PS and the processor chip 800 may be electrically connected to the package substrate 600 through the conductive bumps 720 disposed on the lower pad 705.

The interconnection structure 710 is disposed on an upper surface of the substrate 701 and may include an interlayer insulating layer 711 and a single-layer wiring structure 712 or a multilayer wiring structure 712. When the interconnection structure 710 is formed as a multilayer wiring structure, wiring patterns on different layers may be connected to each other through contact vias. The upper pad 704 connected to the wiring structure 712 may be disposed on the interconnection structure 710. The package structure PS and the processor chip 800 may be connected to the upper pad 704 through the connection bump 139.

The through-via 730 may extend from an upper surface of the substrate 701 to a lower surface and may penetrate the substrate 701. For example, the through-via 730 may extend into the interconnection structure 710 and may be electrically connected to the wirings of the interconnection structure 710. When the substrate 701 is silicon, the through-via 730 may be referred to as TSV.

The interposer substrate 700 may be used to convert or transmit an input electrical signal between the package substrate 600 and the package structure PS or the processor chip 800. Accordingly, the interposer substrate 700 may not include devices such as active devices or passive devices. Accordingly, in the example embodiment, the interconnection structure 710 may be disposed below the substrate 701.

The conductive bump 720 may be disposed on a lower surface of the interposer substrate 700 and may be electrically connected to a wiring of the interconnection structure 710. The interposer substrate 700 may be mounted on the package substrate 600 through the conductive bump 720. For example, a portion of the lower pads 705 used for power or ground may be integrated and connected together to the conductive bump 720, such that the number of lower pads 705 may be greater than the number of conductive bumps 720.

The logic chip or the processor chip 800 may include, for example, a central processor (CPU), graphics processor (GPU), field programmable gate array (FPGA), digital signal processor (DSP), encryption processor, microprocessor, microcontroller, analog-to-digital converter, and application-specific semiconductor (ASIC). Depending on the types of integrated circuits included in the logic chip 800, the semiconductor package 10B may be referred to as a server-oriented semiconductor package or a mobile-oriented semiconductor package. Accordingly, in the example embodiment, the number of the logic chip 800 and/or the package structure PS mounted on the interposer substrate 700 may be greater or less than the examples illustrated in the drawing.

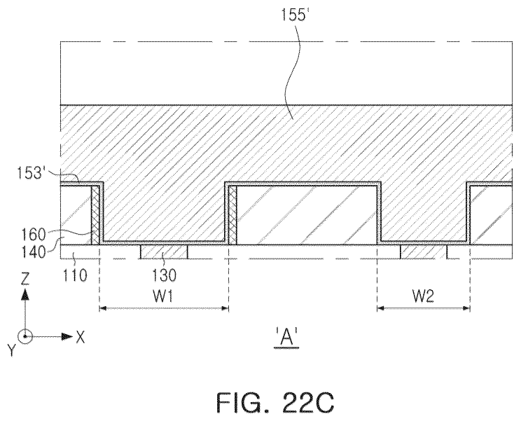

FIGS. 21A to 21E are cross-sectional diagrams illustrating processes of manufacturing some of components of a semiconductor package in FIG. 2A in order.

Referring to FIG. 21A, a plurality of recess regions RS1 and RS2 having different widths may be formed in on a first insulating layer 140 on a first substrate 110. The plurality of recess regions RS1 and RS2 may be formed using a photosensitive material layer and a photolithography process. A width of first recess region RS1 may be greater than a width of second recess region RS2.

Referring to FIG. 21B, a preliminary first buffer layer 160′ covering an upper surface of the first insulating layer 140, a side surface of the first insulating layer 140 exposed by the plurality of recess regions RS1 and RS2, and the preliminary first buffer layer 160′ covering an upper surface of the first substrate 110 and an upper surface of the at least one of the plurality of through-electrodes 130 may be formed. The preliminary first buffer layer 160′ may include a porous metal and may be formed using a plating process. The void included in the porous metal of the preliminary first buffer layer 160′ may be formed, for example, by forming a mixed metal of copper (Cu) and zinc (Zn) through a plating process and selectively etching only zinc (Zn).

Referring to FIG. 21C, the first buffer layer 160′ may be formed by removing the preliminary first buffer layer 160′ of the remaining portion other than the portion formed in the first recess region RS1. The removal of the preliminary first buffer layer 160′ may be performed, for example, using a photolithography process. A first width W1 of the first recess region RS1 after forming the first buffer layer 160′ may be greater than a second width W2 of the second recess region RS2.

Referring to FIG. 21D, the first insulating layer 140, the first buffer layer 160, the preliminary first seed layer 153′ covering an upper surface of the first substrate 110 exposed by the second recess region RS2 and an upper surface of the at least one of the plurality of through-electrodes 130 may be formed. The preliminary first seed layer 153′ may be formed using, for example, a plating process, a PVD process, or a CVD process.

Referring to FIG. 21E, a preliminary first upper conductive layer 155′ may be formed on the preliminary first seed layer 153′. The preliminary first upper conductive layer 155′ may be formed, for example, by a plating process, a PVD process, or a CVD process. Thereafter, referring to FIG. 2A, through the planarization process, the preliminary first upper conductive layer 155′ and the preliminary first seed layer 153′ on a level higher than and upper surface of the first insulating layer 140 may be removed, and a plurality of first upper pads 150 may be formed. The manufacturing process described with reference to FIGS. 21A to 21E may also be applied to the second insulating layer 240 of the second semiconductor chip 200 and the plurality of second lower pads 250.

Hereinafter, in the description of the manufacturing method, descriptions overlapping those described with reference to FIGS. 21A to 21E will not be provided.

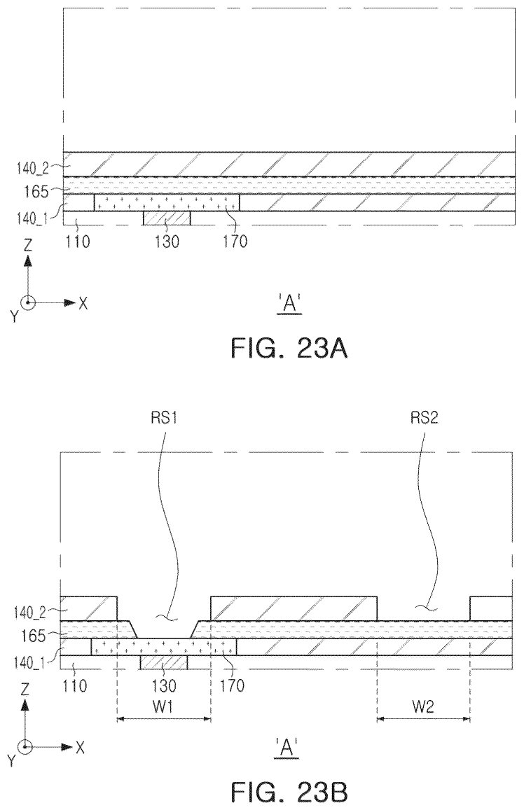

FIGS. 22A to 22C are cross-sectional diagrams illustrating processes of manufacturing some of components of a semiconductor package in FIG. 4 in order.

Referring to FIG. 22A, a plurality of recess regions RS1 and RS2 may be formed by patterning the first insulating layer 140, and the preliminary first buffer layer 160′ may be formed. The preliminary first buffer layer 160′ may include porous metal and also polymer. When the preliminary first buffer layer 160′ includes a polymer, the preliminary first buffer layer 160′ may be formed using, for example, a PVD process or a CVD process. When the preliminary first buffer layer 160′ includes a porous metal, the preliminary first buffer layer 160′ may be formed in the same manner as described with reference to FIG. 21B.

Referring to FIG. 22B, the first buffer layer 160′ may be formed by removing the portion other than the side surface portion of the first buffer layer 160 exposed by the preliminary first buffer layer 160′ and the first recess region RS1.

Referring to FIG. 22C, a preliminary first seed covering an upper surface of the first substrate 110 and an upper surface of the at least one of the plurality of through-electrodes 130 exposed by the first insulating layer 140, the first buffer layer 160, and the plurality of recess regions RS1 and RS2 layer 153′ may be formed. A preliminary first upper conductive layer 155′ may be formed on the preliminary first seed layer 153′. Thereafter, referring to FIG. 4, the preliminary first upper conductive layer 155′ and the preliminary first seed layer 153′ on a level higher than an upper surface of the first insulating layer 140 may be removed and a plurality of first upper pads 150 may be formed.

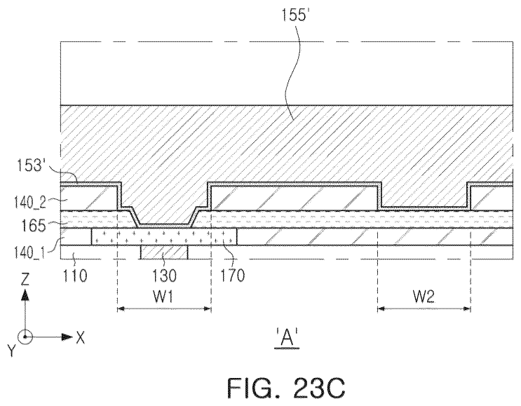

FIGS. 23A to 23C are cross-sectional diagrams illustrating processes of manufacturing some of components of a semiconductor package in FIG. 14.

Referring to FIG. 23A, a first connection conductor 170 in contact with a through-electrode 130 on a first substrate 110 and a first internal insulating layer 140_1 surrounding a side surface of the first connection conductor 170 may be formed on the first substrate 110. Also, the first buffer insulating layer 165 may be formed on the first internal insulating layer 140_1, and the first external insulating layer 140_2 may be formed on the first buffer insulating layer 165. The first buffer insulating layer 165 and the first external insulating layer 140_2 may be formed using, for example, a PVD process, a CVD process, or a spin coating process.

Referring to FIG. 23B, the first recess region RS1 may be formed by etching a portion of the first external insulating layer 140_2 and the first buffer insulating layer 165 to expose a portion of an upper surface of the first connection conductor 170. Also, a second recess region RS2 having the second width W2 substantially the same as the first width W1 of the first recess region RS1 may be formed.

Referring to FIG. 23C, a preliminary first seed layer 153′ covering an upper surface of the first external insulating layer 140_2 and the portions exposed by the plurality of recess regions RS1 and RS2 may be formed, and as preliminary first upper conductive layer 155′ may be formed on the preliminary first seed layer 153′. Thereafter, referring back to FIG. 14, the preliminary first upper conductive layer 155′ and the preliminary first seed layer 153′ on a level higher than an upper surface of the first external insulating layer 140_2 may be removed and a plurality of first upper pads 150 may be formed.

According to the aforementioned example embodiments, by including a buffer layer surrounding a portion of a pad, a stack of semiconductor chips having a high-quality bonding interfacial surface may be implemented, and a semiconductor package having improved reliability may be provided.

While the example embodiments have been illustrated and described above, it will be configured as apparent to those skilled in the art that modifications and variations may be made without departing from the scope in the example embodiment as defined by the appended claims.

1. A semiconductor package comprising:
a first semiconductor chip comprising:
a first substrate,
a plurality of first upper pads on the first substrate, wherein the plurality of first upper pads comprise a first group of the first upper pads and a second group of the first upper pads,
a first buffer layer surrounding a side surface of the first group of the first upper pads,
a first insulating layer surrounding a side surface of the second group of the first upper pads and a side surface of the first buffer layer, and
a plurality of through-electrodes penetrating the first substrate, the plurality of through-electrodes being respectively connected to the plurality of the first upper pads; and
a second semiconductor chip on the first semiconductor chip, comprising:
a second substrate,
a plurality of second lower pads below the second substrate, wherein the plurality of second lower pads comprises a first group of the second lower pads and a second group of the second lower pads,
a second buffer layer surrounding a side surface of the first group of the second lower pads, and
a second insulating layer surrounding a side surface of the second group of the second lower pads and a side surface of the second buffer layer,
wherein the first group of the first upper pads is respectively in contact with the first group of the second lower pads, and
wherein the second group of the first upper pads is respectively in contact with the second group the second lower pads.

2. The semiconductor package of claim 1, wherein the first buffer layer comprises a first material having a first Young's modulus that is lower than a second Young's modulus of a second material in the plurality of first upper pads, and
wherein the second buffer layer comprises a third material having a third Young's modulus that is lower than a fourth Young's modulus of a fourth material in the plurality of second lower pads.

3. The semiconductor package of claim 1, wherein a first width of the first group of the first upper pads is greater than a second width of the second group of the first upper pads in a direction parallel to an upper surface of the first semiconductor chip.

4. The semiconductor package of claim 1, wherein a first thickness of the first group of the first upper pads is greater than a second thickness of the second group of the first upper pads in a direction perpendicular to an upper surface of the first semiconductor chip.

5. The semiconductor package of claim 1, further comprising a bonding film between the first insulating layer and the second insulating layer.

6. The semiconductor package of claim 1, further comprising a second connection conductor in contact with an upper surface of the first group of the second lower pads below the second substrate.

7. The semiconductor package of claim 6, further comprising:
a second buffer insulating layer configured to divide the second insulating layer into a second internal insulating layer and a second external insulating layer,
wherein the second internal insulating layer is configured to surround a side surface of the second connection conductor below the second substrate,
wherein the second buffer insulating layer is in contact with a side surface of the first group of the second lower pads and an upper surface of the second group of the second lower pads below the second internal insulating layer and the second connection conductor, and
wherein the second external insulating layer is configured to surround a side surface of the first group of the second lower pads and a side surface of the second group of the second lower pads below the second buffer insulating layer.

8. The semiconductor package of claim 7, wherein the first group of the second lower pads comprises:
a second layer portion below the second buffer insulating layer, and
a second extension portion extending from an upper surface of the second layer portion, penetrating the second buffer insulating layer, and being in contact with the second connection conductor.

9. The semiconductor package of claim 8, wherein the second extension portion has a width decreasing toward the second connection conductor.

10. The semiconductor package of claim 7, wherein the second buffer insulating layer comprises at least one of silicon oxide, silicon nitride, silicon oxynitride, and silicon carbonitride.

11. The semiconductor package of claim 6, wherein the second connection conductor comprises at least one of aluminum (Al), copper (Cu), and alloys of Al and Cu.

12. The semiconductor package of claim 1, wherein the first buffer layer comprises a polymer or a porous metal, and
wherein the second buffer layer comprises the polymer or the porous metal.

13. The semiconductor package of claim 1, wherein the first insulating layer and the second insulating layer comprise at least one of silicon oxide, silicon nitride, silicon oxynitride, and silicon carbonitride.

14. A semiconductor package comprising:
a first semiconductor chip and a second semiconductor chip stacked in a vertical direction,
wherein the first semiconductor chip comprises:
a plurality of first upper pads comprising:
a first upper conductive layer, and
a first upper seed layer surrounding a side surface of the first upper conductive layer and a lower surface of the first upper conductive layer;
a first buffer layer extending along at least one perimeter of a first upper pad in a first set of the plurality of first upper pads; and
a first insulating layer surrounding the first upper pad and the first buffer layer of a second set of the plurality of first upper pads,
wherein the second semiconductor chip comprises:
a plurality of second lower pads comprising:
a second lower conductive layer, and
a second lower seed layer surrounding a side surface of the second lower conductive layer and an upper surface of the second lower conductive layer, the of the second lower conductive layer being electrically connected to the plurality of first upper pads;
a second buffer layer extending along at least one perimeter of a second lower pad in a first set of the plurality of second lower pads; and
a second insulating layer surrounding the second lower pad and the second buffer layer in a second set of the plurality of second lower pads,
wherein the first buffer layer and the second buffer layer comprise a polymer or a porous metal.

15. The semiconductor package of claim 14, wherein at least one of the plurality of first upper pads is in direct contact with at least one of the plurality of second lower pads.

16. The semiconductor package of claim 14, wherein the first upper conductive layer and the second lower conductive layer comprise copper (Cu), and
wherein the first upper seed layer and the second lower seed layer comprise at least one of titanium (Ti), titanium nitride (TiN), tantalum (Ta), and tantalum nitride (TaN).

17. A semiconductor package comprising:
a first semiconductor chip comprising a plurality of upper pads; and
a second semiconductor chip comprising:
a plurality of lower pads comprising a first group of lower pads and a second group of the lower pads in contact with an upper surface of the plurality of upper pads,
a connection conductor in contact with an upper surface of the first group of the lower pads,
an internal insulating layer surrounding a side surface of the connection conductor,
a buffer insulating layer in contact with a side surface of the first group of the lower pads and an upper surface of the second group of the lower pads, and
an external insulating layer surrounding a side surface of the first group of the lower pads and a side surface of the second group of the lower pads below the buffer insulating layer,
wherein the first group of the lower pads comprises:
a layer portion surrounded by the external insulating layer, and
an extension portion extending from an upper surface of the layer portion, penetrating the buffer insulating layer, and being in contact with a lower surface of the connection conductor.

18. The semiconductor package of claim 17, wherein the buffer insulating layer comprises at least one of silicon oxide, silicon nitride, silicon oxynitride, and silicon carbonitride.

19. The semiconductor package of claim 17, further comprising a buffer layer covering the layer portion in the external insulating layer.

20. The semiconductor package of claim 19, wherein a thickness of the first group of the lower pads is greater than a thickness of the second group the lower pads in a direction perpendicular to the lower surface of the connection conductor.

21-26. (canceled)
